(19) United States
(12) Patent Application Publication
(10) Pub. No.: US 2026/0240038 A1
(43) Pub. Date: Aug. 13, 2026

(54) SEMICONDUCTOR PACKAGE AND MANUFACTURING METHOD THEREOF

(71) Applicant: Taiwan Semiconductor Manufacturing Company, Ltd., Hsinchu (TW)

(72) Inventors: Yen-Pu Chen, Hsinchu (TW); Sheng-Han Tsai, Hsinchu (TW); Tsung-Yu Chen, Hsinchu City (TW); Kris Lipu Chuang, Hsinchu City (TW)

(73) Assignee: Taiwan Semiconductor Manufacturing Company, Ltd., Hsinchu (TW)

(21) Appl. No.: 19/047,638

(22) Filed: Feb. 7, 2025

(51) Int. Cl. H01L 23/16; H01L 21/48; H01L 23/00; H01L 23/053; H01L 23/10; H01L 23/498; H01L 25/16

(52) U.S. Cl. CPC H10W 76/40; H10W 70/65; H10W 76/01; H10W 76/15; H10W 76/60; H10W 90/00; H10W 72/354; H10W 74/15; H10W 90/724; H10W 90/734; H10W 90/736

(57) ABSTRACT

A semiconductor package includes a package substrate, a semiconductor die, a lid, and a reinforcement brick. The semiconductor die is disposed on the package substrate. The lid is attached to the package substrate and comprising a sidewall portion arranged along a periphery of the package substrate to demarcate a package space. The semiconductor die is within the package space. The reinforcement brick is disposed within the package space and located between the sidewall portion of the lid and the semiconductor die. The reinforcement brick is electrically insulated from the package substrate. A top surface of the semiconductor die keeps a larger distance from the package substrate than a top surface of the reinforcement brick.

### BACKGROUND

Semiconductor packages are used in variety of electronic applications, such as personal computers, cell phones, digital cameras, and other electronic equipment. In terms of the packaging used for integrated circuit components or semiconductor dies, one or more dies or packages are generally bonded to a circuit carrier (e.g., a system board, a printed circuit board, or the like) for electrical connections to other external devices or electronic components. To respond to the increasing demand for miniaturization, higher speed and better electrical performance, more creative packaging and assembling techniques are actively researched.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 5 are cross-sectional views illustrating a method of forming a semiconductor package according to an embodiment of the disclosure.

FIG. 6 to FIG. 7 are cross-sectional views of intermediate steps during the manufacturing of a semiconductor package according to an embodiment of the disclosure.

FIG. 8 is a cross-sectional view illustrating a semiconductor package according to an embodiment of the disclosure.

FIG. 9 is a top view illustrating a semiconductor package according to an embodiment of the disclosure.

FIG. 10 is a top view illustrating a semiconductor package according to an embodiment of the disclosure.

FIG. 11 is a top view illustrating a semiconductor package according to an embodiment of the disclosure.

FIG. 12 is a cross-sectional view of a portion of a semiconductor package according to an embodiment of the disclosure.

FIG. 13 is a cross-sectional view of the semiconductor package in FIG. 12 in a warped state.

FIG. 14 is a cross-sectional view of a portion of a semiconductor package according to an embodiment of the disclosure.

FIG. 15 is a cross-sectional view of the semiconductor package in FIG. 14 in a warped state.

FIG. 16 is a top view illustrating a semiconductor package according to an embodiment of the disclosure.

FIG. 17 is a cross-sectional view illustrating a semiconductor package according to an embodiment of the disclosure.

FIG. 18 is a cross-sectional view illustrating a semiconductor package according to an embodiment of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

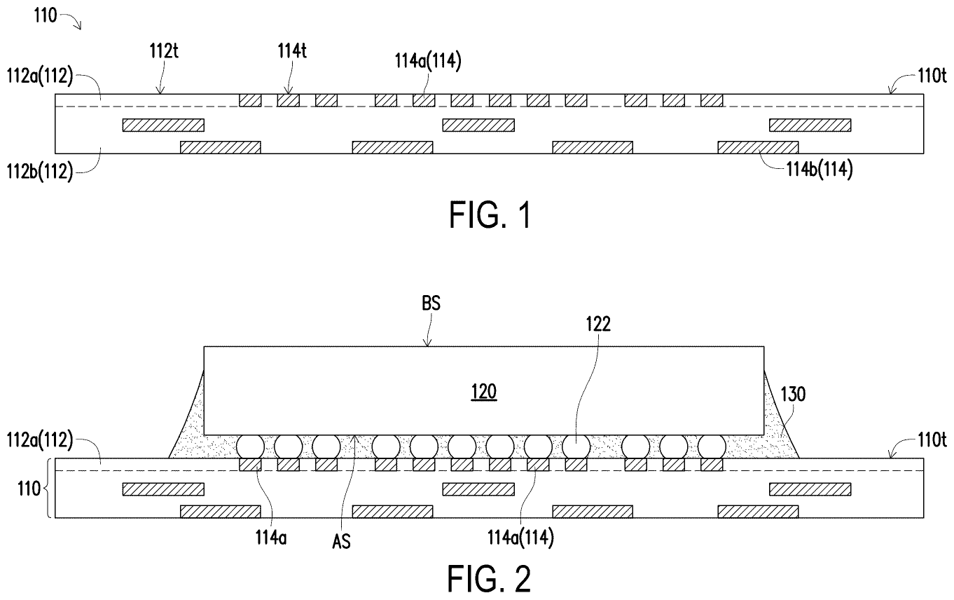

Referring to FIG. 1, a package substrate 110 is provided. For example, the package substrate 110 includes a dielectric structure 112 and a conductive structure 114 embedded in the dielectric structure 112. The dielectric structure 112 may include glass fiber, resin, filler, pre-preg, epoxy, silica filler, Ajinomoto Build-up Film (ABF), polyimide, molding compound, other materials, and/or combinations thereof. The conductive structure 114 may include one or more conductive materials such as gold (Au), copper (Cu), silver (Ag), nickel (Ni), tin (Sn), palladium (Pd), other materials, and/or combinations thereof. In the embodiment, the dielectric structure 112 includes a top dielectric layer 112a and other dielectric layers 112b underlying the top dielectric layer 112a, while the conductive structure 114 includes a plurality of pads 114a exposed by the top dielectric layer 112a and other conductive features/patterns 114b formed in the other dielectric layers 112b. The top dielectric layer 112a is a top-most dielectric layer in the dielectric structure 112 and a top surface 112t of the top dielectric layer 112a forms a top surface 110t of the package substrate 110. In the embodiment, top surfaces 114t of the pads 114a and the top surface 112t of the top dielectric layer 112a are substantially coplanar. In unillustrated embodiment, the top surfaces 114t of the pads 114a are higher than the top surface 112t of the top dielectric layer 112a.

In unillustrated embodiments, the package substrate 110 may include a substrate core. In some embodiments, the substrate core may be made of a semiconductor material such as silicon, germanium, diamond, or the like. Alternatively, the substrate core may be made of a compound material such as silicon germanium, silicon carbide, gallium arsenic, indium arsenide, indium phosphide, silicon germanium carbide, gallium arsenic phosphide, gallium indium phosphide, and/or combinations thereof. In some alternative embodiments, the substrate core may be made of an insulating core such as a fiberglass reinforced resin core. In some embodiments, a core material of the fiberglass reinforced resin core includes fiberglass resin such as FR4, bismaleimide-triazine (BT) resin, Ajinomoto build-up film (ABF), and/or combinations thereof.

Referring to FIG. 2, a semiconductor die 120 is bonded on the top surface 110t of the package substrate 110. For example, the semiconductor die 120 is a package component for a chip-on-wafer-on-substrate (CoWoS) device, thereby the semiconductor die 120 is a suitable chip-on-wafer (CoW) package component. In some embodiments, the semiconductor die 120 may be a logic die (e.g., a central processing unit (CPU), a graphics processing unit (GPU), an application processor (AP), a microcontroller, a memory die (e.g., a dynamic random access memory (DRAM), a static random access memory (SRAM), etc.), a power management die (e.g., a power management integrated circuit (PMIC)), a radio frequency (RF) die, a micro-electro-mechanical-system (MEMS) die, a signal processing die, or the like.

The semiconductor die 120 may include an active surface AS (such as a bottom surface of the semiconductor die 120 as shown in FIG. 2) and a backside surface BS opposite to the active surface AS (such as a top surface of the semiconductor die 120 as shown in FIG. 2), and the active surface AS is faced to the package substrate 110. For example, a plurality of conductive connectors 122 are formed on the active surface AS, and the semiconductor die 120 is bonded on the package substrate 110 through the conductive connectors 122. In some embodiments, the conductive connectors 122 are attached to the pads 114a exposed by the top dielectric layer 112a of the package substrate 110, such that the conductive connectors 122 are directly in contact with the pads 114a to form an electrical connection between the semiconductor die 120 and the package substrate 110. In some embodiments, the conductive connectors 122 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. Further, each of the conductive connectors 122 may include solder, copper, aluminum, gold, nickel, silver, palladium, tin, the like, or combinations thereof. In some embodiments, the conductive connectors 122 are formed by initially forming a layer of solder through evaporation, electroplating, printing, solder transfer, ball placement, or the like. Once the layer of solder has been formed on the structure, a reflow may be performed in order to shape the material into the desired bump shapes.

As shown in FIG. 2, a package underfill 130 is formed between the semiconductor die 120 and the package substrate 110, and surrounding the conductive connectors 122. For example, the package underfill 130 may be dispensed in a gap between the active surface AS of the semiconductor die 120 and the package substrate 110. The package underfill 130 may reduce stress and protect the joints resulting from the conductive connectors 122. In some embodiments, the package underfill 130 may include a suitable underfill material, such as a curable polymeric material. The package underfill 130 may be drawn into the gap between the active surface AS of the semiconductor die 120 and the package substrate 110 by a capillary process or the like.

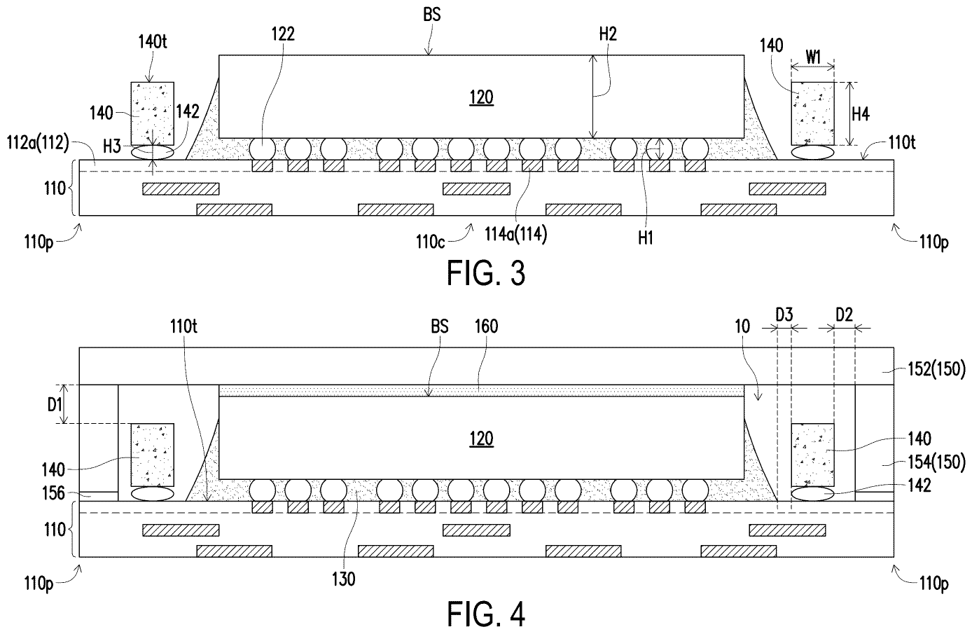

Referring to FIG. 3, a reinforcement brick 140 is disposed over the package substrate 110, wherein the reinforcement brick 140 is electrically insulated from the package substrate 110. In the embodiment, the reinforcement brick 140 is attached on the top surface 110t of the package substrate 110 through an adhesive layer 142. In the embodiment, the adhesive layer 142 includes an insulating adhesive having epoxy, silicone, polyimide, or other type of adhesive. In some embodiments, the adhesive layer 142 may not involve an electric conductive property. For example, the adhesive layer 142 is laterally spaced from the pads 114a exposed by the top dielectric layer 112a of the package substrate 110, and the adhesive layer 142 is directly in contact with the top dielectric layer 112a of the package substrate 110.

In the embodiment, the reinforcement brick 140 is not a passive device or other electronic components and no electric connection is required for the reinforcement brick 140. The reinforcement brick 140 may include a bulk material. For example, the bulk material may include Al, Cu, or Si, or the like, and the reinforcement brick 140 is free from an electronic function.

In FIG. 3, the backside surface BS of the semiconductor die 120 keeps a larger distance from the package substrate 110 than a top surface 140t of the reinforcement brick 140. For example, the top surface 140t of the reinforcement brick 140 is located between the backside surface BS of the semiconductor die 120 and the top surface 110t of the package substrate 110. In the embodiment, a distance of the backside surface BS relative to the top surface 110t of the package substrate 110 is greater than a distance of the top surface 140t of the reinforcement brick 140 relative to the top surface 110t of the package substrate 110. In the embodiment, the distance of the backside surface BS relative to the top surface 110t of the package substrate 110 is a sum of a height H1 of one of the conductive connectors 122 and a height H2 of the semiconductor die 120, and the distance of the top surface 140t of the reinforcement brick 140 relative to the top surface 110t of the package substrate 110 is a sum of a height H3 of the adhesive layer 142 and a height H4 of the reinforcement brick 140.

The package substrate 110 has a center 110c and a periphery 110p surrounding the center 110c, wherein the semiconductor die 120 is located on the center 110c. In some embodiments, the height H4 and a width W1 in direction the center 110c towards periphery 110p of the reinforcement brick 140 may influence a volume of the reinforcement brick 140, the volume may affect the anti-warpage effect, thereby the height H4 ranges from 1 mm to 3 mm, and the width W1 ranges from 5 mm to 20 mm to achieved better anti-warpage effect.

Referring to FIG. 4, after disposing the reinforcement brick 140, a lid 150 is attached to the package substrate 110, and a package space 10 is formed between the lid 150 and the package substrate 110. In the embodiment, the lid 150 may include a cover portion 152 and a sidewall portion 154 extending from the cover portion 152 to the package substrate 110. In some embodiments, the lid 150 is made of aluminum, steel, copper, or an alloy of these metals. As an example, the cover portion 152 and the sidewall portion 154 may be pre-assembled before attaching to the package substrate 110, or the cover portion 152 and the sidewall portion 154 may be an integrated structure through suitable molding process.

In the embodiment, the sidewall portion 154 of the lid 150 is arranged along a periphery 110p of the package substrate 110 to demarcate a package space 10, and the semiconductor die 120 and the reinforcement brick 140 may be located within the package space 10. For example, in the package space 10, the reinforcement brick 140 is spaced from the cover portion 152 with a distance D1, the reinforcement brick 140 is spaced from the sidewall portion 154 with a distance D2, and the reinforcement brick 140 is spaced from the package underfill 130 with a distance D3. In some embodiments, the distance D1 may range from 0.1 mm to 0.5 mm, the distance D2 may range from 5 mm to 10 mm, and the distance D3 may range from 5 mm to 10 mm.

In FIG. 4, the lid 150 may be attached on the top surface 110t of the package substrate 110 through an adhesive layer 156, and the lid 150 may be attached on the backside surface BS of the semiconductor die 120 through the thermal interface material (TIM) feature 160. In some embodiments, a material of the adhesive layer 156 is same as a material of the adhesive layer 142. In some embodiments, a material of the adhesive layer 156 is different from a material of the adhesive layer 142. In some embodiments, the thermal interface material feature 160 is applied to the backside surface BS of the semiconductor die 120, and the thermal interface material feature 160 may include, but is not limited to, a thermal grease, a phase change material, or the like.

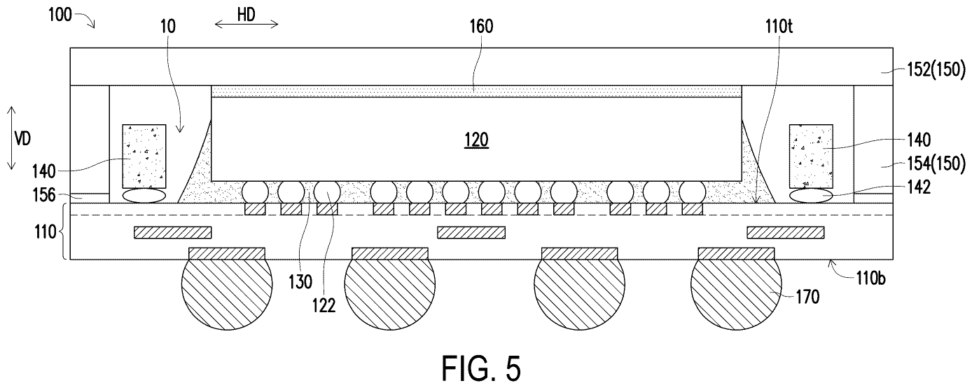

Referring to FIG. 5, a plurality of external terminals 170 are formed on a bottom surface 110b of the package substrate 110 and electrically coupled to the package substrate 110 to form a semiconductor package 100, wherein the bottom surface 110b is opposite to the top surface 110t. The external terminals 170 may be used to bond the package substrate 110 to a circuit board (not shown). In some embodiments, the external terminals 170 provide an electrical connection for signal transmitting and power delivering. The external terminals 170 may include one or more combinations of a stud, a pillar, a bump, or a solder ball, among other examples. In some embodiments, the external terminals 170 include one or more materials, such as gold (Au), copper (Cu), silver (Ag), nickel (Ni), tin (Sn), a lead (Pb), or a palladium (Pd), among other examples. In some embodiments, the one or more materials may be lead-free (e.g., Pb-free). In some embodiments, the external terminals 170 correspond to C4 connection structures.

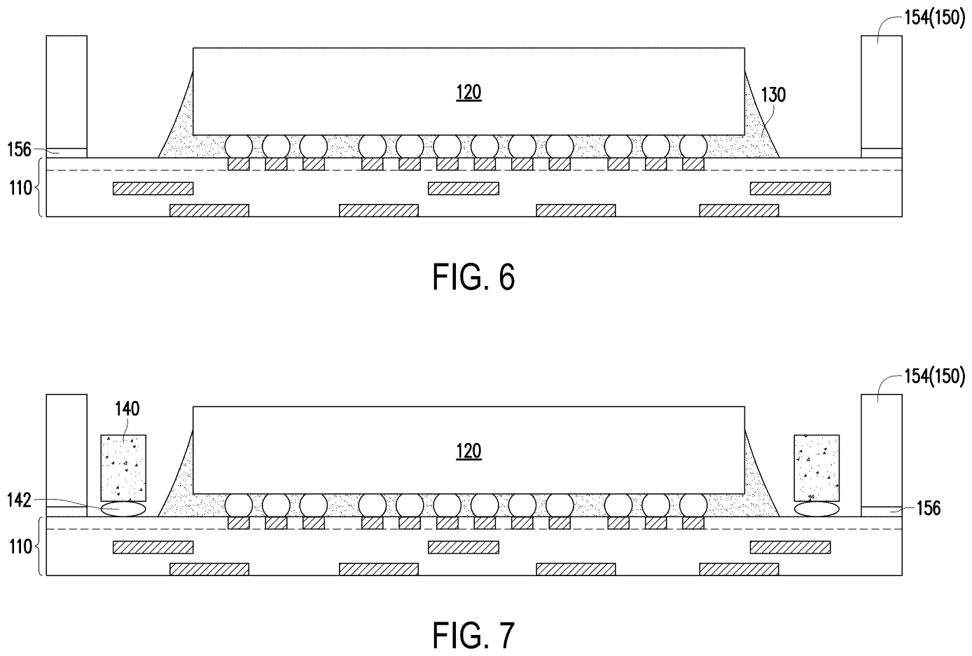

Referring to FIG. 2, FIG. 6, FIG. 7, and FIG. 4, another steps design for attaching the lid 150 may be used. First, following the step shown in FIG. 2, when the semiconductor die 120 are bonded on the package substrate 110 and the package underfill 130 is formed, the sidewall portion 154 of the lid 150 is attached to the package substrate 110 through the adhesive layer 156, while the cover portion 152 of the lid 150 may not be disposed on the package substrate 110 in this step, as shown in FIG. 6. After attaching the sidewall portion 154 of a lid 150, the reinforcement brick 140 is disposed over the package substrate 110 and between the semiconductor die 120 and the sidewall portion 154 laterally, as shown in FIG. 7 through the adhesive layer 142. Then, the cover portion 152 may attach onto the sidewall portion 154, as shown in FIG. 4. In this way, the sidewall portion 154 and the cover portion 152 of the lid 150 are attached in separate steps.

Referring to FIG. 5, the semiconductor package 100 includes the reinforcement brick 140 disposed within the package space 10 and located between the sidewall portion 154 of the lid 150 and the semiconductor die 120. Moreover, the reinforcement brick 140 may cover 15% to 30% of a peripheral area located between the semiconductor die 120 and the lid 150. By designing the reinforcement brick 140 to the semiconductor package 100, the overall structural rigidity of the semiconductor package 100 may be improved, which helps to reduce the risk of adverse effects caused by an excessive warpage of the semiconductor package 100. In some embodiments, the excessive warpage of the semiconductor package 100 may occur during reliability testing, etc., and/or may occur during an operation of the semiconductor die 120 in a field application. The adverse effects caused by the excessive warpage of the semiconductor package 100 may include the deformation of the thermal interface material feature 160 to the cover portion 152, the peeling of the adhesive layer 142/156, the poor connection of the conductive connectors 122, or the like. The reinforcement brick 140 may increase the overall structural rigidity of the semiconductor package 100, and/or change the overall mechanical stress distribution in the semiconductor package 100, which may reduce the risk of the above adverse effects. For example, a stiffness of the reinforcement brick 140 is greater than 70 GPa, and the stiffness of the package substrate 110 is smaller than 30 GPa, thereby the reinforcement brick 140 may effectively enhance the overall structural rigidity.

In FIG. 5, the semiconductor package 100 includes the package substrate 110, the semiconductor die 120, the reinforcement brick 140, the lid 150, and the external terminals 170. In the embodiment, the semiconductor die 120, the reinforcement brick 140 and the lid 150 are disposed on the package substrate 110. In a vertical direction VD of the semiconductor package 100, the backside surface BS of the semiconductor die 120 keeps a larger distance from the package substrate 110 than a top surface 140t of the reinforcement brick 140, and the cover portion 152 of the lid 150 is overlying the sidewall portion 154 of the lid 150, the semiconductor die 120, and the reinforcement brick 140. In a horizontal direction HD, the reinforcement brick 140 is disposed in the gap between the semiconductor die 120 and the sidewall portion 154 of the lid 150. The semiconductor die 120 is electrically coupled to the external terminals 170 through the package substrate 110. The reinforcement brick 140 and the lid 150 are electrically insulated from the package substrate 110. Further, the semiconductor die 120 may be bonded on the package substrate 110 through the conductive connectors 122, the reinforcement brick 140 may be attached on the package substrate 110 through the adhesive layer 142, the lid 150 may be attached on the package substrate 110 through the adhesive layer 156, and the lid 150 may be attached on the semiconductor die 120 through the thermal interface material feature 160. Moreover, the package underfill 130 is formed between the semiconductor die 120 and the package substrate 110, and surrounding the conductive connectors 122.

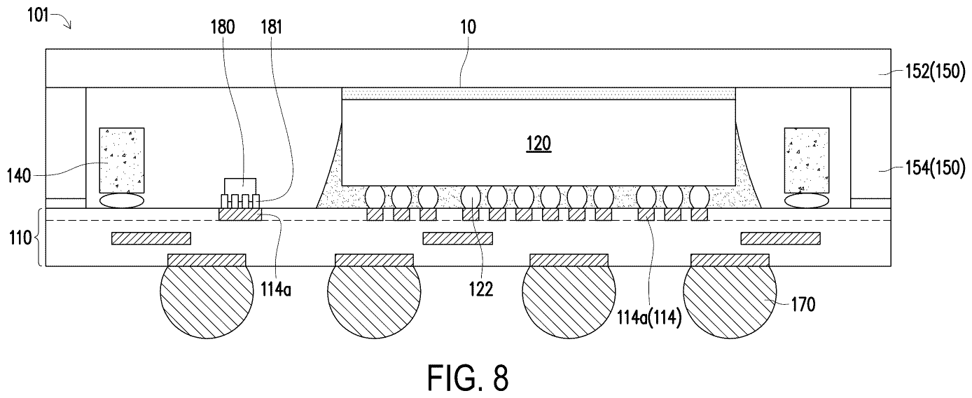

Referring to FIG. 8, a semiconductor package 101 includes similar features as the semiconductor package 100 and includes the package substrate 110, the semiconductor die 120, the reinforcement brick 140, the cover portion 152 of the lid 150, the sidewall portion 154 of the lid 150, and the external terminals 170. A difference between the semiconductor package 101 and the semiconductor package 100 may include that the semiconductor package 101 further include at least one passive device 180. The passive device 180 is disposed on the package substrate 110 and located beside the reinforcement brick 140 in the semiconductor package 101. Here, any suitable number of the passive device 180 may be used. In some embodiments, the passive device 180 is bonded to the pads 114a through conductive connectors 181. In some embodiments, the passive device 180 is a discrete capacitor, a discrete inductor, a discrete resistor, or the like. In some embodiments, a size of the passive device 180 may ranges from 0.3 mm×0.6 mm to 1.6 mm×0.8 mm. The size of the passive device 180 may be smaller than a size of the reinforcement brick 140. In an unillustrated embodiment, a plurality of passive devices and a plurality of reinforcement bricks are provided, and numbers of the reinforcement brick may be greater than number of the passive devices.

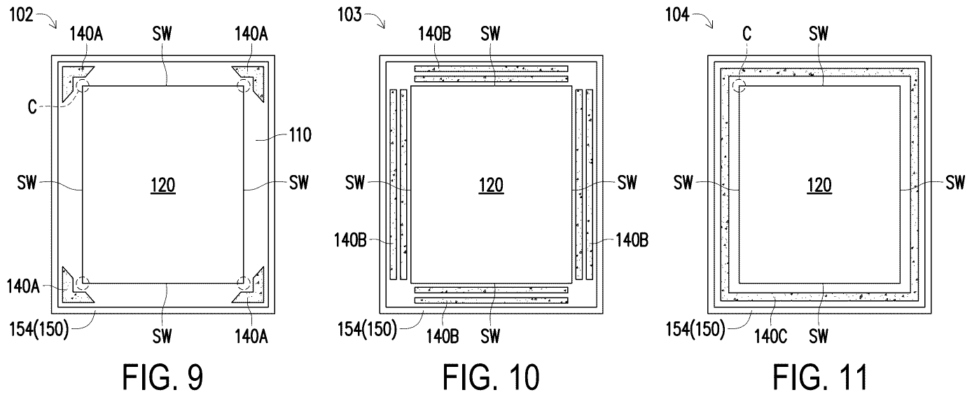

Referring to FIG. 9, in the top view, the shown components of a semiconductor package 102 includes the package substrate 110, the semiconductor die 120, the reinforcement brick 140A, and the lid 150. The semiconductor package 102 may have a cross-sectional view similar to the semiconductor package depicted in FIG. 5 while the cover portion of the lid 150 and the external terminals 170 are not illustrated in FIG. 9 for clearly presenting the disposition relationship between these components. The semiconductor die 120 disposed on the package substrate 110 may include four sidewalls SW, and adjacent two of the sidewalls SW intersect at one corner C, and therefore, the semiconductor die 120 includes four corners C in the embodiment. The reinforcement bricks 140A are disposed around the semiconductor die 120 and located corresponding to the corners C of the semiconductor die 120. Moreover, the semiconductor die 120 and the reinforcement bricks 140A are surrounded by the sidewall portion 154 of the lid 150. Each of the reinforcement bricks 140A may have a L-like top view pattern to corresponding to the respective corner C of the semiconductor die 120 and the shape of the sidewall portion 154 of the lid 150. In some alternative embodiments, the reinforcement bricks 140A may have other top view patterns.

Referring to FIG. 10, a semiconductor package 103 is similar to the semiconductor package 102 and a difference of the semiconductor package 103 lies in that the semiconductor package 103 includes the reinforcement bricks 140B having linear shapes. The reinforcement bricks 140B are disposed beside the sidewalls SW of the semiconductor die 120. Each of the reinforcement bricks 140B has an elongation shape extending along a corresponding one of the sidewalls SW. As an example, two reinforcement bricks 140B are disposed between one of the sidewalls SW and the sidewall portion 154 of the lid 150, and may have the same length. As another example, the reinforcement bricks 140B corresponding to the same sidewall SW may have different lengths.

Referring to FIG. 11, a semiconductor package 104 is similar to the semiconductor package 102 and a difference of the semiconductor package 103 lies in that the semiconductor package 104 may include the reinforcement brick 140C formed in a continuous ring shape surrounding the semiconductor die 120. For example, the reinforcement brick 140C may be arranged along the corners C and the sidewalls SW of the semiconductor die 120.

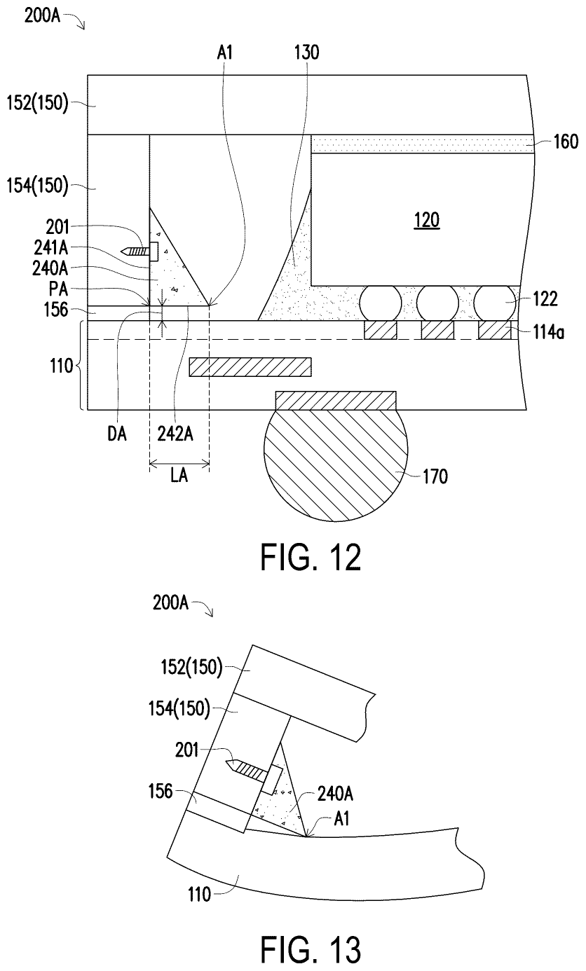

Referring to FIG. 12, FIG. 12 only illustrates a portion of the semiconductor package 200A. The semiconductor package 200A includes the package substrate 110, the semiconductor die 120, the package underfill 130, the reinforcement brick 240A, the lid 150, the thermal interface material feature 160, and the external terminals 170, wherein the structures of the package substrate 110, the semiconductor die 120, the package underfill 130, the lid 150, the thermal interface material feature 160, and the external terminals 170 may be similar to the embodiment of FIG. 5 and are not reiterated here. The semiconductor package 200A is different from the semiconductor package 100 in the design of the reinforcement brick 240A.

In the embodiment, the reinforcement brick 240A is disposed on the sidewall portion 154 of the lid 150 and includes a first surface 241A parallel to the sidewall portion 154 and a second surface 242A extending from the first surface 241A toward the semiconductor die 120. Moreover, a lateral dimension of the reinforcement brick 240A may be gradually reduced from the second surface 242A toward the cover portion 152 of the lid 150. For example, the reinforcement brick 240A may have a triangular shape in the cross-sectional view. In the embodiment, the first surface 241A and the second surface 242A in the cross-sectional view are intersected at a point PA, and the second surface 242A in the cross-sectional view extends laterally from the point PA to a point A1. An extending length LA of the second surface 242A extending from the first surface 241A toward the semiconductor die 120 may be a lateral distance from the point PA to the point A1, in which the lateral direction is a direction parallel to the plane of the semiconductor die 120. The second surface 242A keeps a shorter distance DA from the package substrate 110 than from the cover portion 152, and the extending length LA of the second surface 242A is greater than the shorter distance DA. In some embodiments, the shorter distance DA may range from 200 μm to 400 μm. The semiconductor package 200A may further includes a fastener 201 configured for fixing the reinforcement brick 240A to the sidewall portion 154. For example, the fastener 201 penetrates reinforcement brick 240A and is screwed into the sidewall portion 154. The fastener 201 may be a screw bolt or the like. In the embodiment, the reinforcement brick 240A and the sidewall portion 154 may have through holes corresponding to each other to accommodate the fastener 201.

In the embodiment, the semiconductor package 200A may be fabricated by providing the lid 150, fixing the reinforcement brick 240A to the sidewall portion 154 of the lid 150, bonding the semiconductor die 120 on the package substrate 110, and attaching the lid 150 to the package substrate 110. In some embodiments, the package substrate 110 may suffer certain stress caused by the processes of fabricating the package substrate 110 and bonding the semiconductor die 120 to the package substrate 110. Therefore, before attaching the lid 150 onto the package substrate 110, the package substrate 110 may involve a certain level of warpage, or the stress imbalance of the package substrate 110 may be determined/measured. The reinforcement brick 240A may be fixed onto the sidewall portion 154 of the lid 150 based on the warpage and/or the stress imbalance of the package substrate 110.

For example, in the semiconductor package 200A, an upward warpage of the package substrate 110 is determined or the stress imbalance of the package substrate 110 indicates that an upward warpage of the package substrate 110 tends to occur. The upward warpage may result in that the periphery of the package substrate 110 is bended toward the side of the semiconductor die 120. Therefore, the reinforcement brick 240A may be fixed on the sidewall portion 154 in a manner to resist the upward warpage. For example, the second surface 242A keeps the shorter distance DA from the package substrate 110 than from the cover portion 152 of the lid 150. As such, the reinforcement brick 240A may resist or limit further upward warpage of the package substrate 110 after attaching the lid 150 with the reinforcement brick 240A onto the package substrate 110.

FIG. 13 shows the semiconductor package 200A in an upward warpage state. In some embodiments, the semiconductor package 200A may suffer certain stress during a reliability test of the semiconductor die 120 or the operation of the semiconductor die 120 and the stress may enhance the upward warpage of the package substrate 110 as shown in FIG. 13. In the embodiment, the point A1 of the reinforcement brick 240A may be moving downward to the package substrate 110 under the upward warpage of the package substrate 110, and the point A1 may be in contact with the surface of the package substrate 110, so that the upward warpage of the package substrate 110 is limited.

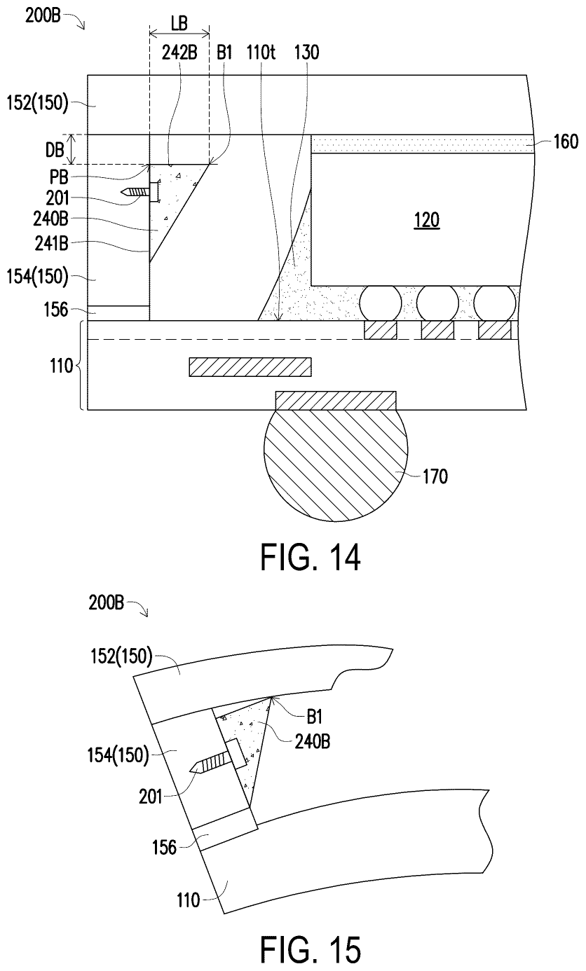

Referring to FIG. 14, FIG. 14 only illustrates a portion of the semiconductor package 200B. The semiconductor package 200B includes the package substrate 110, the semiconductor die 120, the reinforcement brick 240B, the lid 150, and the fastener 201. The semiconductor package 200B may be similar to the semiconductor package 200A depicted in FIG. 12. Specifically, the semiconductor package 200B is different from the semiconductor package 200A in the orientation of the reinforcement brick 240B. In the embodiment, the reinforcement brick 240B is disposed on the sidewall portion 154 of the lid 150 and includes a first surface 241B parallel to the sidewall portion 154 and a second surface 242B extending from the first surface 241B toward the semiconductor die 120. In the embodiment, the first surface 241B and the second surface 242B are intersected to form a point PB and the second surface 242B extends from the point PB to the point B1. The second surface 242B keeps a shorter distance DB from the cover portion 152 than from the package substrate 110, and the extending length LB of the second surface 242B is greater than the shorter distance DB. Therefore, a lateral dimension of the reinforcement brick 240B may be gradually reduced from the cover portion 152 of the lid 150 toward the second surface 242A. In some embodiments, the shorter distance DB may range from 0.1 mm to 0.5 mm.

During fabricating the semiconductor package 200A, a downward warpage of the package substrate 110 is determined or the stress imbalance of the package substrate 110 indicates that a downward warpage of the package substrate 110 tends to occur. The upward warpage may result in that the periphery of the package substrate 110 is bended toward the side of the external terminal 170. Therefore, the reinforcement brick 240B may be fixed on the sidewall portion 154 in a manner to resist or limit the downward warpage. For example, the second surface 242B keeps the shorter distance DB from the cover portion 152 of the lid 150 than from the package substrate 110. As such, the reinforcement brick 240B may resist or limit further upward warpage of the package substrate 110.

FIG. 15 shows the semiconductor package 200B in a downward warpage state. In some embodiments, the semiconductor package 200B may suffer certain stress during a reliability test of the semiconductor die 120 or the operation of the semiconductor die 120 and the stress may enhance the downward warpage of the package substrate 110 as shown in FIG. 15. In the embodiment, the point B1 of the reinforcement brick 240B may move upwardly toward the cover portion 154 of the lid 150 under the downward warpage of the package substrate 110, and the point B1 may be in contact with the surface of the cover portion 154 of the lid 150, so that the downward warpage of the package substrate 110 is limited.

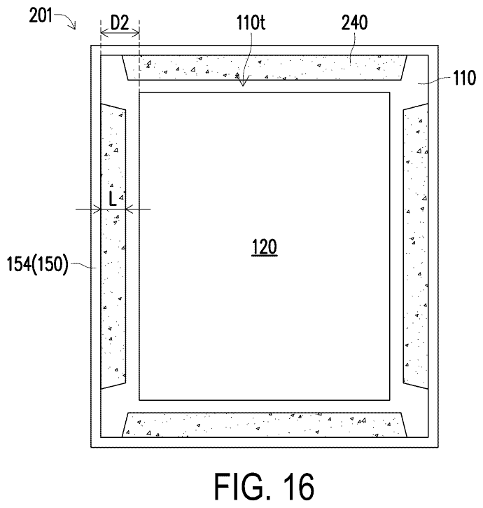

FIG. 16 is a top view of a semiconductor package 201 according to an embodiment of the disclosure. Herein, the structure of the semiconductor package 200A shown in FIG. 12 or the structure of the semiconductor package 200B shown in FIG. 14 may be an implemental example of the cross-section of the semiconductor package 201 in FIG. 16. In addition, the structure of the semiconductor package 201 shown in FIG. 16 may be an implemental example of the top view structure of the semiconductor package 200A in FIG. 12 or the semiconductor structure in FIG. 14. For illustrative purposes, the cover portion 152 of the lid 150 depicted in FIG. 12/14 is not illustrated in FIG. 16. Specifically, the semiconductor package 201 includes the package substrate 110, the semiconductor die 120, the reinforcement brick 240, and the lid 150. The reinforcement brick 240 (corresponded to the reinforcement brick 240A or the reinforcement brick 240B) may be in a shape of a trapezoid in the top view. Moreover, the extending length L (corresponded to the extending length LA or the extending length LB) extending from the sidewall portion 154 of the lid 150 toward the semiconductor die 120 may be 30% to 50% of a lateral distance D2 between the lid 150 and the semiconductor die 120 to ensure sufficient movement distance for the reinforcement brick 240 (corresponded to the reinforcement brick 240A or the reinforcement brick 240B).

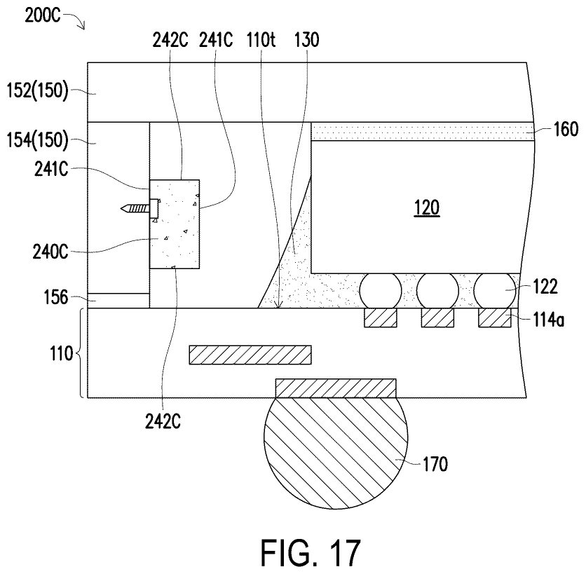

Referring to FIG. 17, FIG. 17 only illustrates a portion of the semiconductor package 200C. The semiconductor package 200C includes the package substrate 110, the semiconductor die 120, the package underfill 130, the reinforcement brick 240C, the lid 150, the thermal interface material feature 160, and the external terminals 170, wherein the structures of the package substrate 110, the semiconductor die 120, the package underfill 130, the lid 150, the thermal interface material feature 160, and the external terminals 170 may be similar to the embodiment of FIG. 5 and are not reiterated here. The semiconductor package 200C is different from the semiconductor package 100 in the design of the reinforcement brick 240C. In addition, the semiconductor package 200C is different from the semiconductor package 200A in the design of the reinforcement brick 240C.

In the embodiment, the reinforcement brick 240C is disposed on the sidewall portion 154 of the lid 150 and includes a pair of the first surface 241C and a pair of the second surface 242C. Moreover, a lateral dimension of the reinforcement brick 240C may be substantially uniform. For example, the reinforcement brick 240C may have a rectangle shape in the cross-sectional view, thereby the reinforcement brick 240C may apply to two warpage conditions, such as the upward warpage and the downward warpage, therefore, the reinforcement brick 240C has more flexibility in use.

For example, in the semiconductor package 200C, an upward warpage of the package substrate 110 in FIG. 13 or a downward warpage of the package substrate 110 in FIG. 15 are determined or the stress imbalance of the package substrate 110 indicates that an upward warpage of the package substrate 110 or a downward warpage of the package substrate 110 tend to occur. Therefore, the reinforcement brick 240C may be fixed on the sidewall portion 154 in a manner to resist the upward warpage or the downward warpage.

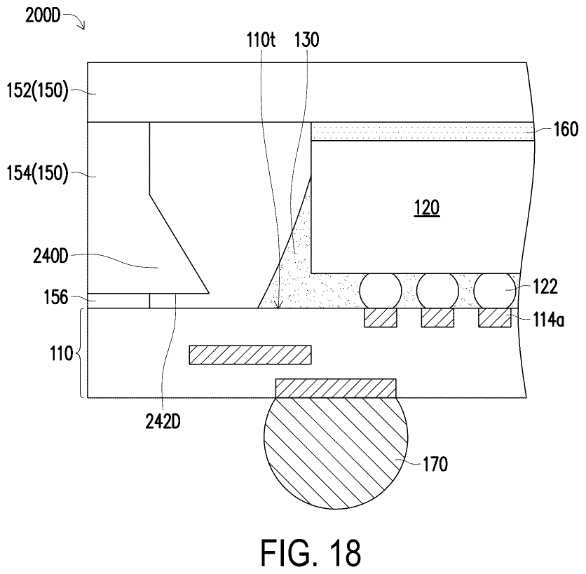

Referring to FIG. 18, FIG. 18 only illustrates a portion of the semiconductor package 200D. The semiconductor package 200D includes the package substrate 110, the semiconductor die 120, the package underfill 130, the reinforcement brick 240D, the lid 150, the thermal interface material feature 160, and the external terminals 170. The semiconductor package 200D may be similar to the semiconductor package 200A depicted in FIG. 12. Specifically, the semiconductor package 200D is different from the semiconductor package 200A of the reinforcement brick 240D. In the embodiment, the reinforcement brick 240B is disposed on the sidewall portion 154 of the lid 150 and the reinforcement brick 240D and the lid 150 is an integrated structure to decrease manufacturing cost. For example, a material of the reinforcement brick 240D is same as a material of the lid 150 and a surface 242D of the reinforcement brick 240D is directly in contact with the lid 150.

In accordance with some embodiments of the present disclosure, a semiconductor package includes a package substrate, a semiconductor die, a lid, and a reinforcement brick. The semiconductor die is disposed on the package substrate. The lid is attached to the package substrate and comprising a sidewall portion arranged along a periphery of the package substrate to demarcate a package space. The semiconductor die is within the package space. The reinforcement brick is disposed within the package space and located between the sidewall portion of the lid and the semiconductor die. The reinforcement brick is electrically insulated from the package substrate. A top surface of the semiconductor die keeps a larger distance from the package substrate than a top surface of the reinforcement brick. In an embodiment, the semiconductor package further includes an adhesive layer. The reinforcement brick is attached to the package substrate through the adhesive layer. In an embodiment, the package substrate includes a top dielectric layer and pads exposed by the top dielectric layer, and the adhesive layer is directly in contact with the top dielectric layer and laterally spaced from the pads. In an embodiment, the reinforcement brick covers 15% to 30% of a peripheral area between the semiconductor die and the lid. In an embodiment, the reinforcement brick is a bulk material, and the bulk material has a stiffness greater than 70 GPa. In an embodiment, a plurality of the reinforcement brick is disposed around the semiconductor die. In an embodiment, the reinforcement brick is in a continuous ring shape surrounding the semiconductor die.

In accordance with some embodiments of the present disclosure, a semiconductor package includes a package substrate, a semiconductor die, a lid, and a reinforcement brick. The semiconductor die is disposed on the package substrate. The lid is attached to the package substrate. The lid includes a cover portion and a sidewall portion extending from the cover portion to the package substrate. The reinforcement brick is located on the sidewall portion. The reinforcement brick comprises a surface extends from the sidewall portion toward the semiconductor die. In an embodiment, the surface keeps a shorter distance from the package substrate than from the cover portion, an extending length of the surface extending from the sidewall portion toward the semiconductor die is greater than the shorter distance. In an embodiment, the surface keeps a shorter distance from the cover portion than from the package substrate, an extending length of the surface extending from the sidewall portion toward the semiconductor die is greater than the shorter distance. In an embodiment, the semiconductor package further includes a fastener fixing the reinforcement brick to the sidewall portion. In an embodiment, the fastener is screwed in the sidewall portion. In an embodiment, the semiconductor package further includes an adhesive layer disposed between the lid and the package substrate. In an embodiment, the semiconductor package further includes a package underfill located between the semiconductor die and the package substrate. The reinforcement brick is spaced from the package underfill with a distance. In an embodiment, an extending length of the surface extending from the sidewall portion toward the semiconductor die is 30% to 50% of a lateral distance between the lid and the semiconductor die.

In accordance with some embodiments of the present disclosure, a manufacturing method of a semiconductor package, includes: providing a package substrate; bonding a semiconductor die to the package substrate; disposing a reinforcement brick over the package substrate, wherein the reinforcement brick is electrically insulated from the package substrate and is laterally spaced from the semiconductor die; and attaching a lid to the package substrate, such that a package space is formed between the lid and the package substrate, wherein the reinforcement brick and the semiconductor die are located within the package space. In an embodiment, the reinforcement brick is attached onto the package substrate prior to attaching the lid to the package substrate. In an embodiment, the reinforcement brick is laterally spaced from the lid. In an embodiment, the reinforcement brick is fixed on the lid prior to attaching the lid to the package substrate. In an embodiment, the reinforcement brick is attached onto the package substrate through an adhesive layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a package substrate;
a semiconductor die, disposed on the package substrate;
a lid, attached to the package substrate and comprising a sidewall portion arranged along a periphery of the package substrate to demarcate a package space, wherein the semiconductor die is within the package space; and
a reinforcement brick, disposed within the package space and located between the sidewall portion of the lid and the semiconductor die, wherein the reinforcement brick is electrically insulated from the package substrate, and a top surface of the semiconductor die keeps a larger distance from the package substrate than a top surface of the reinforcement brick.

2. The semiconductor package as claimed in claim 1, further comprising: an adhesive layer, wherein the reinforcement brick is attached to the package substrate through the adhesive layer.

3. The semiconductor package as claimed in claim 2, wherein the package substrate comprises a top dielectric layer and pads exposed by the top dielectric layer, and the adhesive layer is directly in contact with the top dielectric layer and laterally spaced from the pads.

4. The semiconductor package as claimed in claim 1, wherein the reinforcement brick covers 15% to 30% of a peripheral area between the semiconductor die and the lid.

5. The semiconductor package as claimed in claim 1, wherein the reinforcement brick is a bulk material, and the bulk material has a stiffness greater than 70 GPa.

6. The semiconductor package as claimed in claim 1, wherein a plurality of the reinforcement brick is disposed around the semiconductor die.

7. The semiconductor package as claimed in claim 1, wherein the reinforcement brick is in a continuous ring shape surrounding the semiconductor die.

8. A semiconductor package, comprising:
a package substrate;
a semiconductor die, disposed on the package substrate;
a lid, attached to the package substrate, wherein the lid comprises a cover portion and a sidewall portion extending from the cover portion to the package substrate; and
a reinforcement brick, located on the sidewall portion, wherein:
the reinforcement brick comprises a surface extends from the sidewall portion toward the semiconductor die.

9. The semiconductor package as claimed in claim 8, wherein the surface keeps a shorter distance from the package substrate than from the cover portion, and an extending length of the surface extending from the sidewall portion toward the semiconductor die is greater than the shorter distance.

10. The semiconductor package as claimed in claim 8, wherein the surface keeps a shorter distance from the cover portion than from the package substrate, and an extending length of the surface extending from the sidewall portion toward the semiconductor die is greater than the shorter distance.

11. The semiconductor package as claimed in claim 8, further comprising: a fastener fixing the reinforcement brick to the sidewall portion.

12. The semiconductor package as claimed in claim 11, wherein the fastener is screwed in the sidewall portion.

13. The semiconductor package as claimed in claim 8, further comprising: an adhesive layer disposed between the lid and the package substrate.

14. The semiconductor package as claimed in claim 13, further comprising: a package underfill located between the semiconductor die and the package substrate, wherein the reinforcement brick is spaced from the package underfill with a distance.

15. The semiconductor package as claimed in claim 8, wherein an extending length of the surface extending from the sidewall portion toward the semiconductor die is 30% to 50% of a lateral distance between the lid and the semiconductor die.

16. A manufacturing method of a semiconductor package, comprising:
providing a package substrate;
bonding a semiconductor die to the package substrate;
disposing a reinforcement brick over the package substrate, wherein the reinforcement brick is electrically insulated from the package substrate and is laterally spaced from the semiconductor die; and
attaching a lid to the package substrate, such that a package space is formed between the lid and the package substrate, wherein the reinforcement brick and the semiconductor die are located within the package space.

17. The manufacturing method of a semiconductor package as claimed in claim 16, wherein the reinforcement brick is attached onto the package substrate prior to attaching the lid to the package substrate.

18. The manufacturing method of a semiconductor package as claimed in claim 17, wherein the reinforcement brick is laterally spaced from the lid.

19. The manufacturing method of a semiconductor package as claimed in claim 16, wherein the reinforcement brick is fixed on the lid prior to attaching the lid to the package substrate.

20. The manufacturing method of a semiconductor package as claimed in claim 16, wherein the reinforcement brick is attached onto the package substrate through an adhesive layer.
